(19) United States
(12) Patent Application Publication
(10) Pub. No.: US 2007/0007969 A1
(43) Pub. Date: Jan. 11, 2007

(54) Circuit and system for detecting dc component in inverter device for grid-connection

(75) Inventors: Zheng Dai, Tokyo (JP); Yosuke Harada, Tokyo (JP); Motoyasu Sato, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: EBARA DENSAN LTD., Tokyo (JP)

(21) Appl. No.: 10/570,610

(22) PCT Filed: Aug. 26, 2004
(86) PCT No.: PCT/JP04/12706

§ 371 Date: Mar. 3, 2006

(30) Foreign Application Priority Data
Sep. 19, 2003 (JP) 2003-012706

(51) Int. Cl. G01R 35/00

(52) U.S. Cl. 324/601

(57) ABSTRACT

A DC component detecting circuit (18) detects a small DC component contained in the AC output power of a grid-connection inverter device (12), accurately within a short period of time, and has a simple, small-size, and lightweight configuration. The DC component detecting circuit (18) comprises separators (21, 22) for separating a voltage which is proportional to the output current of the inverter device into voltages in positive and negative half periods, integrators (23, 24) for integrating the separated voltages in the positive and negative half periods, and an adder (25) for adding integral signals in the positive and negative half periods from the integrators (23, 24).

### TECHNICAL FIELD

The present invention relates to a circuit and a system for detecting a DC component in an inverter device for grid-connection, and more particularly to a circuit and a system for detecting a DC component contained in an AC output of an inverter device for grid-connection, accurately within a short period of time.

### BACKGROUND ART

Photovoltaic power generating apparatus or fuel cell power generating apparatus generate DC electric power as generated electric power. For connecting such a power generating apparatus to a commercial AC power supply system, it is customary for an inverter device to convert the DC electric power generated by the power generating apparatus into AC electric power that matches the commercial AC power supply system and to supply the converted AC electric power to the commercial AC power supply system.

It is not desirable if a DC component is contained in the AC electric power waveform, which flows into the commercial AC power supply system. However, due to an offset, temperature characteristics, or etc. of a control system for power switching devices of the inverter device, the converted AC electric power may contain a DC component. Grid-connection standards provide for the limitation of a DC component that can be contained in the AC output power of grid-connection inverter devices. For example, the grid-connection standards require that if a rated alternating current output from a grid-connection inverter device contains a DC component over 0.5%, then the DC component be detected within 500 msec.

A DC component contained in the AC output power from a grid-connection inverter device may be detected by removing an AC component from the AC output power with a filter circuit to extract the DC component.

However, the removal of an AC component having a low frequency of 50 Hz or 60 Hz from the AC output power using a filter circuit requires that the filter circuit have inductors and capacitors of large size and hence be necessarily large in scale.

Furthermore, it is difficult to separate up to 1% of a DC component from the AC output power which contains an AC component in its most part. The output of the filter is greatly affected even when the frequency of the power supply varies slightly. The grid-connection inverter device may occasionally change its output frequency based on its function of active-detecting for an independent operation. In such an occasion, the output of the filter contains an error, which makes it difficult to detect only the DC component with accuracy.

### DISCLOSURE OF INVENTION

The present invention has been made in view of the above drawbacks.

It is an object of the present invention to provide a circuit for detecting a small DC component contained in the AC output power of a grid-connection inverter device, accurately within a short period of time.

Another object of the present invention is to provide such a DC component detecting circuit in a simple, small-size, and lightweight configuration.

According to the present invention, there is provided a DC component detecting circuit for detecting a DC component contained in the output power of a grid-connection inverter device, comprising a current detector for outputting a current signal or a voltage signal which is proportional to an output current of the inverter device, a separating circuit for separating the detected signal from the current detector into signals in respective positive and negative half periods, an integrating circuit for integrating the separated signals in the respective positive and negative half periods, and an adding circuit for adding integral signals in the respective positive and negative half periods from the integrating circuit.

Preferably, the separating circuit comprises two diodes or two ideal diode circuits connected to an output terminal of the current detector and oriented such that currents flow in opposite directions therethrough. The separating circuit thus arranged is capable of separating a voltage proportional to the output current of the inverter device into voltages in the respective positive and negative half periods with a simple circuit arrangement. The integrating circuit preferably comprises a CR-type analog integrating circuit. The integrating circuit thus arranged is capable of integrating the separated voltages in the respective positive and negative half periods with a simple circuit arrangement.

According to the present invention, the AC output power from the inverter device is separated into voltages in respective positive and negative half periods of one cycle, and the separated voltages are integrated in the respective positive and negative half periods of one cycle to calculate the areas of the voltage waveforms. Then, the difference between the calculated areas is calculated to extract the DC component. The DC component detecting circuit is capable of detecting the DC component easily with high accuracy as it separates the AC output power from the inverter device into voltages in respective positive and negative half periods of one cycle, and detects the DC component from the difference between the areas of the voltage waveforms in the respective positive and negative half periods. Since the DC component is detected by comparing the areas of the voltage waveforms in the respective positive and negative half periods, the DC component can be detected in a very short period of time. As the removal of a commercial AC frequency component which has heretofore been required is not necessary, the DC component detecting circuit does not need to have a filter circuit which requires a large installation space and which is not accurate, and hence is small in size and lightweight.

Further preferably, the DC component detecting circuit further comprises memory means for holding calibrating information for the detected signal depending on a temperature drift of the current detector. The detected signal representative of the DC component is calibrated based on the calibrating information stored by the memory means. Preferably, the DC component detecting circuit further comprises a second current detector, which is structurally identical to the current detector, selectively connected to or bypassing the same output line of the inverter device as the current detector is connected. The sum of the DC component contained in the output power of the inverter device and the temperature drift is detected based on the detected signal from the current detector, only a DC component is acquired by the second current detector, and the difference between the detected signal from the current detector and the DC component from the second current detector is calculated as temperature drift calibrating information to calibrate the detected signal from the current detector. With this arrangement, even when the detected signal from the current detector contains a temperature drift component, the detected signal is calibrated as an appropriate detected signal.

According to the present invention, there is also provided a DC component detecting system for detecting a DC component contained in the output power of a grid-connection inverter device, comprising a grid-connection inverter device, a current detector for outputting a voltage which is proportional to an output current of the inverter device, a DC component detecting circuit for separating a detected signal from the current detector into signals in respective positive and negative half periods, integrating the separated signals in the respective positive and negative half periods, and adding integral signals from the integrating circuit in the respective positive and negative half periods to output a DC component of the detected signal, memory means for storing calibrating information for the detected signal depending on a temperature drift of the current detector, and means for calibrating the DC component based on the calibrating information stored by the memory means.

According to the present invention, there is further provided a DC component detecting circuit for detecting a DC component contained in the output power of a grid-connection inverter device, comprising a voltage detector for directly detecting and outputting an output voltage of the inverter device, a separating circuit for separating the detected signal from the current detector into signals in respective positive and negative half periods, an integrating circuit for integrating the separated signals in the respective positive and negative half periods, and an adding circuit for adding integral signals in the respective positive and negative half periods from the integrating circuit.

According to the present invention, a small DC component contained in the AC output power of a grid-connection inverter device can be detected accurately within a short period of time. The DC component detecting circuit does not need a large-size filter circuit for removing a low-frequency component and hence may be in a highly small-size and compact configuration. Even when the current detector suffers a temperature drift, the small DC component can be detected by using a calibrating means or not using a current detector to make the DC component detecting circuit less susceptible to or free of the temperature drift.

### BRIEF DESCRIPTION OF DRAWINGS

FIG. 1 is a block diagram of a power generating system including a DC component detecting circuit according to a first embodiment of the present invention;

FIGS. 2A through 2C are diagrams showing the principles of the DC component detecting circuit according to the first embodiment, FIG. 2A showing one cycle of operation, FIG. 2B a positive half cycle of operation, and FIG. 2C a negative half cycle of operation;

FIGS. 3A and 3B are diagrams showing how the detection of a DC component is affected by harmonic components, FIG. 3A showing an inverter output voltage containing an even harmonic, and FIG. 3A showing an inverter output voltage containing an odd harmonic;

FIG. 4 is a circuit diagram of a specific circuit arrangement of the DC component detecting circuit shown in FIG. 1;

FIGS. 5A and 5B are diagrams showing the manner in which the DC component detecting circuit shown in FIG. 4 operates;

FIG. 6 is a block diagram of a DC component detecting system including a DC component detecting circuit according to a second embodiment of the present invention;

FIG. 7 is a block diagram of a DC component detecting system including a DC component detecting circuit according to a third embodiment of the present invention; and

FIG. 8 is a circuit diagram of a specific circuit arrangement of the DC component detecting circuit shown in FIG. 7.

### BEST MODE FOR CARRYING OUT THE INVENTION

Like or corresponding parts are denoted by like or corresponding reference characters throughout views.

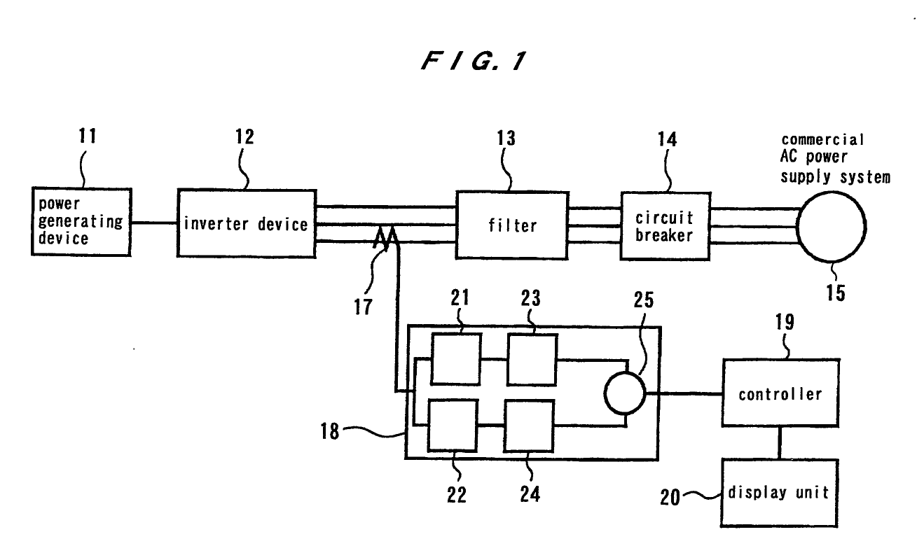

FIG. 1 schematically shows in block form a power generating system including a DC component detecting circuit according to a first embodiment of the present invention. The power generating system includes a power generating device 11 such as a solar cell assembly, a fuel cell assembly,. or the like which generates DC electric power. The generated DC electric power is boosted by a DC/DC converter, not shown, and then supplied to a inverter device 12 for grid-connection. The inverter device 12 detects a voltage waveform from a commercial AC power supply system 15, and controls power switching elements of the inverter device 12 to generate a current waveform whose frequency and phase are in conformity with the detected voltage waveform. The inverter device 12 generates AC electric power that is delivered through a filter 13 and a circuit breaker 14 to the commercial AC power supply system 15. The filter 13 serves to remove a lot of harmonic components generated by the pulse-width modulation (PWM) that is performed by the inverter device 12. The filter 13 includes a filter circuit for preventing electromagnetic induction (EMI) noise from being introduced into the commercial AC power supply system 15.

A current detector (DCCT) 17 is connected to the output of the inverter device 12. Although not shown, the current detector 17 and a DC component detecting circuit 18, to be described below, are associated with each of the three phases of the inverter device 12. The current detector 17 applies its output signal to the DC component detecting circuit 18. The output signal of the current detector 17 is also used to control the current generated by the inverter device 12 and to operate a protection circuit for the circuit breaker 14.

The DC component detecting circuit 18 detects the magnitude of a DC component contained in the AC output current of the inverter device 12. The detected DC component output from the DC component detecting circuit 18 is supplied to a controller 19, which processes the detected DC component. The controller 19 controls a display unit 20 to display the magnitude of the DC component contained in the AC output current of the inverter device 12.

The DC component detecting circuit 18 has separators 21, 22 for separating an AC voltage that is proportional to the output current from the inverter device 12 which is detected by the current detector 17, into voltages in positive and negative half periods of one cycle. The voltages separated in the positive and negative half periods are integrated by respective positive and negative integrators 23, 24, which output integral signals representative of the areas of the voltage waveforms of those voltages. The integral signal representative of the voltage waveform area in the positive half period and the integral signal representative of the voltage waveform area in the negative half period are added to each other by an adder 25, which outputs the difference between the voltage waveform area in the positive half period and the voltage waveform area in the negative half period as the magnitude of the DC component to the controller 19. The controller 19 compares the magnitude of the DC component with a reference value, and displays it as a numerical value such as 0.5% or the like on the display unit 20.

The DC component detecting circuit 18 operates on the principle that an AC waveform free of any DC components has a positive waveform area and a negative waveform area which are equal to each other. Specifically, the DC component detecting circuit 18 calculates the positive waveform area and the negative waveform area of one period of AC electric power, and obtains the magnitude of a DC component contained in the AC electric power from the difference between the positive waveform area and the negative waveform area.

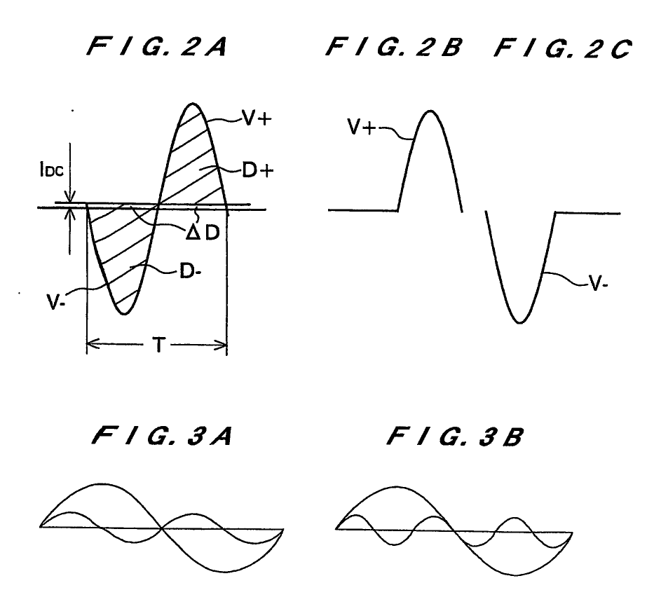

FIGS. 2A through 2C are diagrams showing the principles of the DC component detecting circuit 18. As described above, voltages V+, V− that are proportional to the output current from the inverter device 12 are separated by the separators 21, 22, which produce respective voltage waveforms shown in FIGS. 2B and 2C. The voltages V+, V− separated in respective positive and negative half periods are integrated by the respective integrators 23, 24, which produce integral signals D+, D− representative of the respective areas of the voltage waveforms in the positive and negative half periods. The adder 25 calculates the difference ΔD between the integral signals D+, D− (ΔD=D++D−) to determine the difference between the areas of the voltage waveforms, thus obtaining the magnitude ΔD of the DC component. If the DC component is represented by I_{DC} and the period by T, then the magnitude ΔD of the DC component is calculated by the following equation:
ΔD=2(I_{DC}×T/2)=I_{DC}×T

As described above, the DC component detecting circuit 18 operates in principle by separating one cycle of an AC voltage waveform into a positive half period and a negative half period and calculating the difference between the areas of the voltage waveforms in the positive and negative half periods. The DC component detecting circuit 18 can measure a DC component contained in one period of the AC electric power in principle, and takes 20 msec. to measure such a DC component if the AC electric power has a frequency of 50 Hz and 16.7 msec. to measure such a DC component if the AC electric power has a frequency of 60 Hz. Therefore, even when the inverter device 12 intentionally changes its output frequency for the purpose of detecting an independent operation mode, the DC component detecting circuit 18 can detect a DC component stably irrespective of such a change in the output frequency of the inverter device 12.

The pulse-width-modulated (PWM) output voltage of the inverter device 12 contains a lot of harmonic components. A distorted AC waveform can be broken down into a fundamental wave, even harmonics, and odd harmonics. Since the fundamental wave is symmetrical, the area of the positive half period and the area of the negative half period are equal to each other. An even harmonic has the area of the positive half period and the area of the negative half period that cancel each other within a half cycle of the fundamental wave, as shown in FIG. 3A. As with the fundamental wave, an odd harmonic is symmetrical as shown in FIG. 3B. The odd harmonic has the area of the positive half period and the area of the negative half period that are equal to each other in one cycle of the fundamental wave, and hence is eliminated after those areas are added to each other. Therefore, the detection of a DC component by the DC component detecting circuit 18 is not adversely affected by harmonic components contained in the AC output current of the inverter device 12.

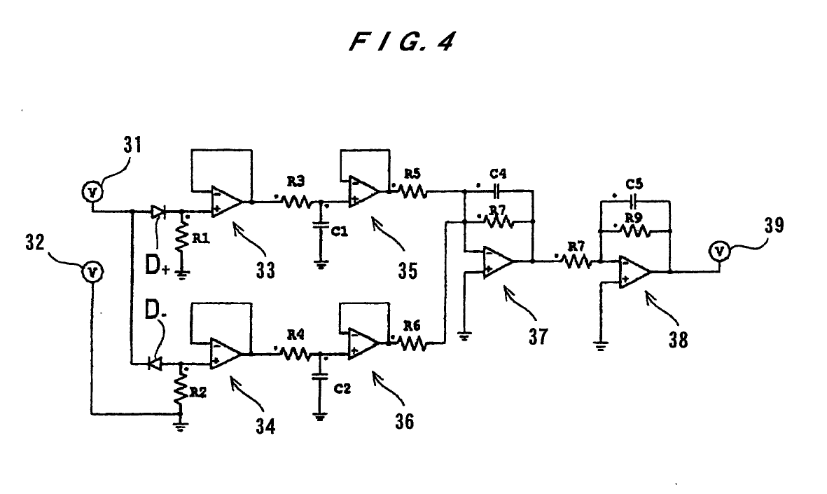

FIG. 4 shows a specific circuit arrangement of the DC component detecting circuit 18. The current detector (DCCT) 17 has output terminals connected to respective input terminals 31, 32 for applying an output signal from the current detector 17 to the input terminals 31, 32. The DC component detecting circuit 18 has separators 33, 34 comprising respective two diodes D+, D− connected to one of the output terminals of the current detector 17, the diodes D+, D− being oriented such that currents flow in opposite directions therethrough, and respective buffers connected to the diodes D+, D−, respectively. When a positive voltage is applied to the input terminal 31, a current flows through the diode D+ and a resistor R1 connected thereto, and when a negative voltage is applied to the input terminal 31, a current flows through the diode D− and a resistor R2 connected thereto. Therefore, the separators 33, 34 output voltage waveforms corresponding to the voltages V+, V− in respective half wave cycles. The two diodes D+, D− may be replaced with two ideal diode circuits.

The separators 33, 34 are followed by respective analog integrators 35, 36 having constants represented by a resistor R3 and a capacitor C1 and a resistor R4 and a capacitor C2. The CR-type analog integrators 35, 36 integrate the voltages V+, V− in respective half wave cycles, and produce integral signals D+, D− representative of the areas of the waveforms of the voltages V+, V− at respective output terminals thereof

The DC component detecting circuit 18 also has adder circuits 37, 38 supplied with an output signal from the integrator 35 which calculates the area of the waveform of the voltage in the positive half period and an output signal from the integrator 36 which calculates the area of the waveform of the voltage in the negative half period. The adder circuits 37, 38 add (cancel) the signals representative of the areas of the waveforms of the voltages in the positive and negative half periods, and output the difference between those signals, i.e., a signal representative of the difference between the areas of the waveforms of the voltages in the positive and negative half periods, as the magnitude ΔD of the DC component, from an output terminal 39. The adder circuits 37, 38 comprise inverting amplifiers having time constants in two stages, and average and add the output signals from the integrators 35, 36. The adder circuit 37 comprises an inverting amplifier adder circuit combined with a parallel connected circuit of a capacitor C4 and a resistor R7 as a feedback circuit, and the adder circuit 38 comprises an inverting amplifier adder circuit combined with a parallel connected circuit of a capacitor C5 and a resistor R9 as a feedback circuit.

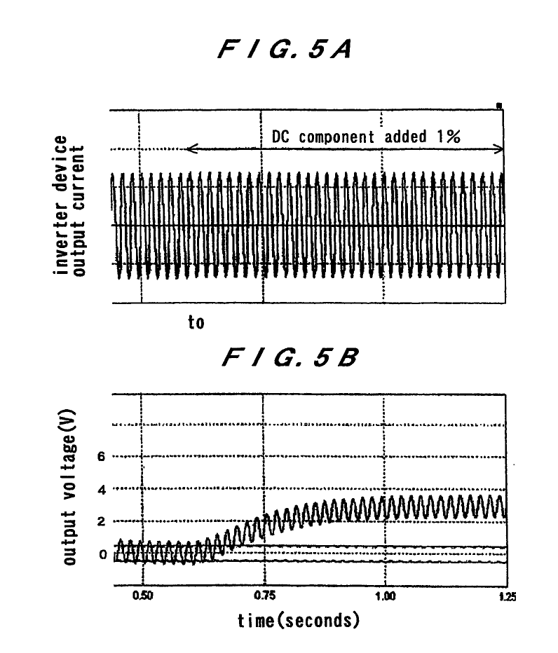

FIGS. 5A and 5B show the results of a simulation on the DC component detecting circuit 18 shown in FIG. 4. FIG. 5A shows the waveform of an AC output current from the inverter device 12, with a step-like DC component being added by 1% to the AC output current from time t₀. The waveform of the AC output current from the inverter device 12 contains second and third harmonics each by 10% and fourth and fifth harmonics each by 5% in order to check the effect that the harmonics have on the operation of the DC component detecting circuit 18.

FIG. 5B shows the waveform of an output voltage from the DC component detecting circuit 18. Time t₀ from which the step-like DC component is added by 1% to the AC output current corresponds to about 0.6 second in the graph shown in FIG. 5B. After the step-like DC component starts being added by 1% to the AC output current, the output voltage from the DC component detecting circuit 18 increases. The output voltage from the DC component detecting circuit 18 is constant after 0.8 through 0.9 second. Therefore, the DC component detecting circuit 18 shown in FIG. 4 is capable of detecting the addition of a DC component to the output current from the inverter device 12 within 0.2 through 0.3 second.

The present grid-connection standards require that the addition of a DC component by 0.5% to the AC output power be detected within 0.5 second. It can be seen that the DC component detecting circuit 18 shown in FIG. 4 can sufficiently meet such a requirement. The time lag of 0.5 second is caused by the time constants of the analog integrators, and, as described above, the DC component detecting circuit 18 is able to measure a DC component in a period of time which corresponds to one cycle of the AC electric power in principle.

The DC component detecting circuit 18 comprises several operational amplifiers, at least two diodes, resistive elements, and capacitive elements. Therefore, the DC component detecting circuit 18 can be mounted on one printed circuit board, or can be constructed as an integrated circuit, and hence can be greatly reduced in size and made compact.

Since the DC component detecting circuit 18 outputs a DC voltage corresponding the DC component introduced into the inverter device 12, the controller 19 can easily convert the DC voltage into a digital signal and process it with a CPU.

The current detector 17 required by the DC component detecting circuit 18 can be used as a current sensor for use in controlling the switching operation of the inverter device 12. The controller 17 can also be used to control the inverter device 12. In this manner, the power generating system can be reduced in cost.

The DC component detecting circuit 18 basically employs the detected signal from the current detector 17, and its offset may cause a temperature drift. The temperature drift is caused when the zero output of a current sensor of the DC component detecting circuit 18 changes (is offset) depending on the temperature. The offset may occasionally change in excess of 0.5% of a rated current. If the current detector of a current sensing circuit is designed to output a voltage of 5 V with respect to a rated current of 10 A, then when there is a temperature drift of 2 mV/° C., the offset changes by 50 mV with a temperature rise of 25° C. Since 0.5% of the output voltage of 5 V is 25 mV, the temperature drift becomes twice the DC component (0.5%) to be detected. Therefore, the DC component detecting circuit 18 which uses the detected current from the current detector 17 suffering the temperature drift detects the temperature drift added to the DC component, and hence tends to suffer an error in the detection of the DC component.

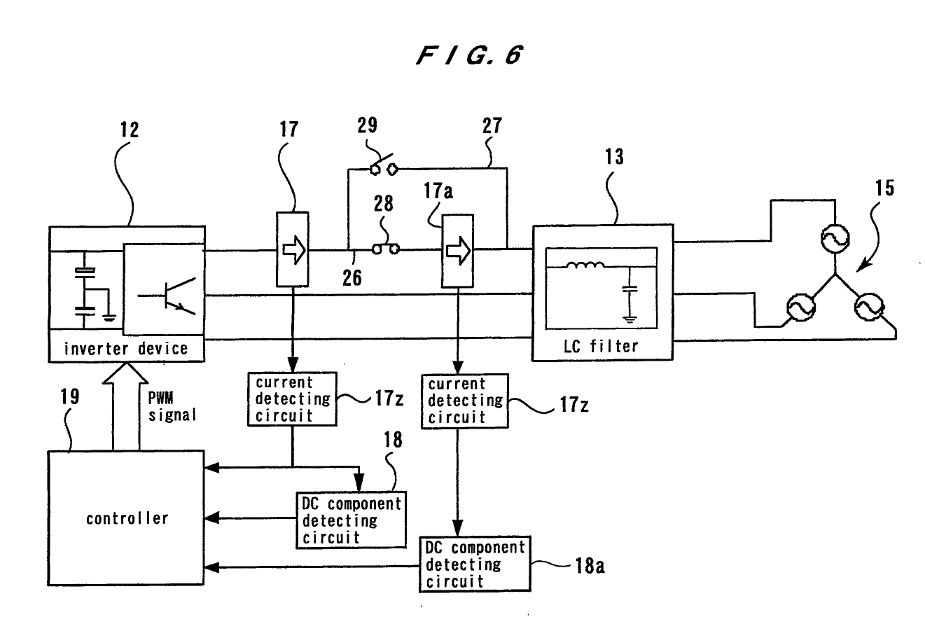

A calibration of the output signal representative of the DC component from the DC component detecting circuit 18 which uses the detected current from the current detector 17 suffering the temperature drift will be described below. FIG. 6 shows in block form a DC component detecting system including a means for calibrating a temperature drift in a DC component detecting circuit according to a second embodiment of the present invention.

As shown in FIG. 6, a second current detector (DCCT) 17a which follows the (first) current detector (DCCT) 17 is connected to an output line 26 of the inverter device 12 in series to the first current detector 17. The output line 26 has a switch 28 between the first and second current detectors 17, 17a, and the second current detector 17a is bypassed by a bypass line 27 having a switch 29. By selectively turning on and off the switches 28, 29, the output current from the inverter device 12 can flow through and bypass the second current detector 17a.

The first current detector 17 is connected to the inverter device 12 at all times because the first current detector 17 is used to control the AC output current of the inverter device 12 and detect the DC component contained in the AC output power. The second current detector 17a serves to calibrate a temperature drift.

The second current detector 17a is identical in structure to the current detector 17. The second current detector 17a sends a detected signal depending on the output current from the inverter device 12 through a current detecting circuit 17z to a DC component detecting circuit 18a. The DC component detecting circuit 18a is identical in circuit arrangement to the DC component detecting circuit 18, and detects the magnitude of a DC component contained in the AC output current from the inverter device 12 based on the detected signal.

When the switch 29 connected to the bypass line 27 is turned off and the switch 28 connected to the output line 26 is turned on, the second current detector 17a is supplied with the same current as the current that flows through the current detector 17. At this time, the DC component detecting circuits 18, 18a individually separate the detected AC voltage into voltages in respective positive and negative half periods, integrate the voltages in the respective positive and negative half periods, and add integral signals in the respective positive and negative half periods to detect and output the difference between the areas of the waveforms of the voltages in the respective positive and negative half periods as the magnitude of a DC component.

At this time, temperature drifts of the current detectors 17, 17a are contained in their detected signals. Specifically, the DC component ΔD contained in the AC output current from the inverter device 12 includes an offset error in addition to a DC current component I_{DC} as indicated by the following equation:
ΔD=(I_{DC}+I_{Offset})×T
where T: the time of one period, and I_{Offset}: an offset voltage as converted into a current.

According to the present embodiment, the same current detector 17a as the current detector 17 is connected to the output of the inverter device 12 in series to the current detector 17, and an offset (I_{Offset}) of the current detector 17 is detected by a process to be described below to calibrate a detected signal from the current detector 17. In this manner, the DC current component I_{DC} can accurately be detected.

A process of calibrating the offset will be described below. When the output current from the inverter device 12 before the power generating system is connected to the commercial AC power supply system 15 is zero, the output signal (DC component ΔD) of the DC component detecting circuit 18 is measured. Since the output current from the inverter device 12 is zero, no DC component is present, and an offset (I_{Offset}) of the current detector 17 can be measured while the current detector 17 is cool. The measured offset (I_{Offset}) is then stored in a memory of the controller 19.

Then, the switch 29 is turned on to connect the bypass line 27 and the switch 28 is turned off, thereby connecting the power generating system to the commercial AC power supply system, i.e., supplying the output current from the inverter device 12 to the commercial AC power supply system 15. After the power generating system is connected to the commercial AC power supply system 15, while a current is flowing through the current detector 17, the output signal (DC component ΔD) of the DC component detecting circuit 18 is measured periodically, e.g., at intervals of 10 msec. Then, the offset (I_{Offset}) of the current detector 17 measured while the current detector 17 is cool is subtracted from the output signal thus measured periodically, thereby measuring the DC current component I_{DC} periodically, e.g., at intervals of 10 msec. During an initial stage after the power generating system is connected to the commercial AC power supply system 15, the temperature of the current detector 17 is low and the current detector 17 does not suffer a temperature drift.

When the current flows through the current detector 17 for a certain period of time and the temperature of the current detector 17 rises, the current detector 17 starts to suffer a temperature drift due to an offset. Now, the offset responsible for the temperature drift is calibrated. Specifically, the calibrating process is performed when the switch 29 is turned on and the switch 28 is turned off. At this time, the AC output current from the inverter device 12 flows through the bypass line 27 which bypasses the current detector 17a.

Then, the output signal from the DC component detecting circuit 18a is detected, and stored in the memory as an offset I_{Offset}_{_{—}}ₐ. Since the output signal from the DC component detecting circuit 18a has zero current and hence does not contain any DC component I_{DC}, only the offset I_{Offset}_{_{—}}ₐ owing to the temperature rise can be detected.

Thereafter, the switch 28 is turned on, and after one second, for example, has elapsed for allowing the current flowing through the output line 26 to be stabilized, the switch 29 is turned off. The AC output current from the inverter device 12 is now switched to flow through the current detector 17a.

Upon elapse of 5 seconds, for example, after the AC output current from the inverter device is switched to flow through the current detector 17a, i.e., when the output current from the current detector 17a is stabilized, the output signal from the DC component detecting circuit 18a is detected once again, and the difference between the detected value and the offset I_{Offset}_{_{—}}ₐ stored in the memory is regarded as the DC component I_{DC} at the present time. Since the current detector 17 and the current detector 17a are connected in series to each other, the DC component I_{DC} is of the same value for the current detector 17 and the current detector 17a. By subtracting the DC component I_{DC} from the output signal of the DC component detecting circuit 18, therefore, the temperature drift caused by the offset of the current detector 17 at the time can be calculated. The data of the temperature drift is then stored in the memory, and will be used as calibrating data for the current detector 17. That is, the proper DC component I_{DC} can be measured from the current detector 17 by calibrating the offset I_{Offset} of the current detector 17 indirectly with the current detector 17a.

When the calibrating process based on the second current detector 17a is over, the switch 29 is turned on, and after one second, for example, has elapsed for allowing the current flowing through the bypass line 27 to be stabilized, the switch 28 is turned off. The AC output current from the inverter device 12 is now switched to flow through the bypass line 27, whereupon the power generating system returns to the steady power outputting mode. When the temperature rises further, e.g., by 5° C. upon continued operation of the power generating system, the above process is repeated to update the data of the temperature drift due to the offset of the current detector 17. The DC component I_{DC} from the output signal of the DC component detecting circuit 18 based on the detected signal from the current detector 17 can be produced in a manner free from the temperature drift due to the offset I_{Offset}.

In the present embodiment, the two identical current detectors 17, 17a are employed to detect and calibrate a temperature drift due to an offset change at all times. However, calibrating information for a detected signal depending on a temperature drift of a single current detector may be acquired in advance and stored in the memory, and the detected signal of the current detector may be calibrated based on the calibrating information stored in the memory. For example, an offset depending on the temperature of the current detector may be acquired and stored as a table in the memory, the temperature of the current detector may be detected, and calibrating information for the offset may be read from the table stored in the memory. In this manner, an accurate DC component I_{DC} can easily be calculated.

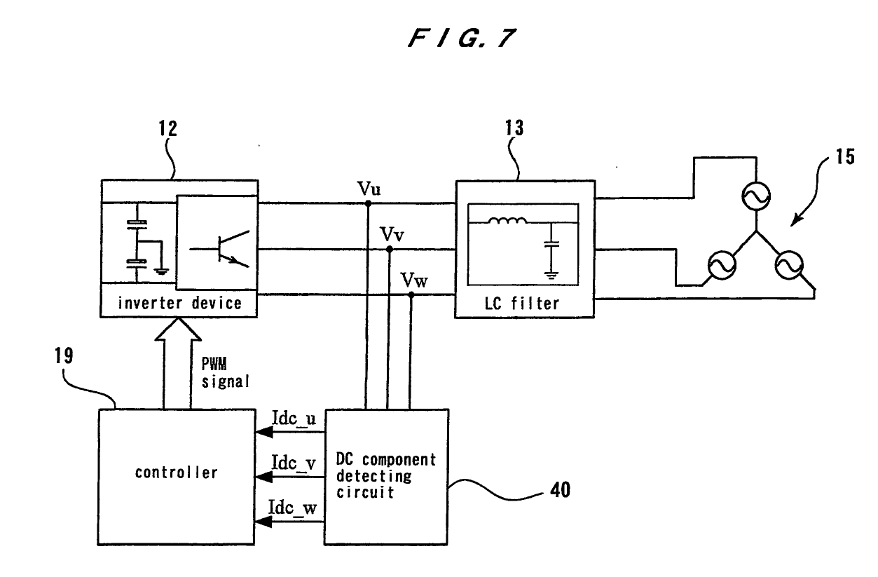

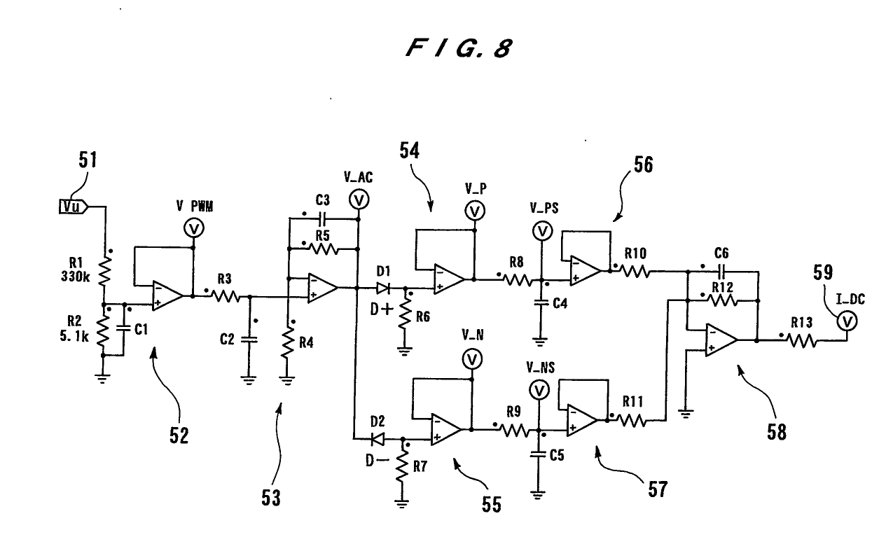

FIGS. 7 and 8 show a DC component detecting system including a DC component detecting circuit according to a third embodiment of the present invention for the grid-connection inverter device. According to the third embodiment, a DC component is detected directly from the output voltage of the inverter device without the need for a current detector (DCCT) which suffers a temperature drift.

Basically, the DC component of an inverter is generated by switching operation of the inverter due to an offset of a sensor as a signal unit, a calculating error of a controller as a command unit, and an asymmetrical nature of power elements as an output unit. As a consequence, the output voltage of the inverter contains a DC component.

As shown in FIG. 7, a DC component detecting circuit (voltage detector) 40 directly detects an output voltage waveform of the inverter device 12. Since a current detector (DCCT) which suffers a temperature drift is not employed, no sensor temperature drift exists. Although not shown, current detectors are connected to the output of the inverter device 12, and the controller 19 performs a current-controlling pulse-width-modulation (PWM) control process for enabling the inverter device 12 to produce a current waveform in phase with the voltage waveform in the commercial AC power supply system 15 based on the currents detected by the current detectors. The inverter device 15 controls the power switching elements thereof in response to a control signal according to the current-controlling PWM control process.

The DC component detecting circuit 40, which includes a voltage detector, is associated with each of the three phases of the inverter device 12. Specifically, the DC component detecting circuit 40 includes a voltage dividing circuit (voltage detector) for directly detecting the output voltage in each phase, and perform a process of detecting the magnitude of a DC component contained in the AC output power from the inverter device 12 in the same manner as described above. The controller 19 processes a detected signal (DC component output ΔD=I_{DC}×T) from the DC component detecting circuit 40, and controls a display unit (not shown) to display the magnitude of the DC component.

After the voltage detection (voltage division) by the DC component detecting circuit 40, as with the previous embodiments, the detected AC voltage is separated into voltages in respective positive and negative half periods, and the separated voltages are integrated. The integral signals in the respective positive and negative half periods are added to calculate and output the difference between the areas of the voltage waveforms as the magnitude ΔD of the DC component according to the following equation:
ΔD=I_{DC}×T (see FIG. 2A)

The magnitude ΔD of the DC component is compared with a reference value. If the magnitude ΔD of the DC component exceeds the reference value, then it is determined as representing a failure.

FIG. 8 shows a specific circuit arrangement of the DC component detecting circuit 40, which is connected to a Vu line of a three-phase system. The circuit arrangement of the component detecting circuit 40 is similar to the circuit arrangement shown in FIG. 4 according to the first embodiment except that an input terminal is connected to a voltage dividing circuit 52 (voltage detector) in an input stage. A divided voltage from voltage dividing circuit 52 is applied to a CR-type integrating circuit, which converts the output voltage waveform (PWM rectangular output voltage waveform) of the inverter device 12 into a smooth sine-wave voltage. The sine-wave voltage is then amplified by a noninverting amplifier 53 combined with a parallel connected circuit of a capacitor and a resistor as a feedback circuit. The amplified voltage is then applied to separators 54, 55 having respective diodes D+, D− that are connected in opposite directions. The separators 54, 55 separate the applied voltage into voltages in respective positive and negative half periods of one cycle. The diodes D+, D− may be replaced with ideal diode circuits.

The output voltages from the separators 54, 55 are applied to respective CR-type analog integrators 56, 57 which integrate the voltages in the respective half wave periods to produce integral signals representative of the areas of the waveforms of the voltages. The integral signals are then sent from analog integrators 56, 57 to an adder 58 which comprises a noninverting amplifier combined with a parallel connected circuit of a capacitor and a resistor as a feedback circuit. The adder 58 adds (cancels) the output signals in the positive and negative half periods from the analog integrators 56, 57, and outputs a signal representative of the difference between the signals, i.e., a signal representative of the difference between the areas of the voltage waveforms in the positive and negative half periods as the magnitude ΔD of the DC component, to an output terminal 59. As described above, the magnitude ΔD of the DC component is expressed as follows:
ΔD=I_{DC}×T

As with the first embodiment, the adder 58 may comprise two amplifiers connected in cascade.

The principle of the measuring process performed by the DC component detecting circuit 40 are identical to that of the DC component detecting circuit 18 according to the first embodiment in that it employs the area of the output waveform from the inverter device. Therefore, the DC component detecting circuit 40 can measure, in principle, a DC component contained in one period of the AC electric power in 20 msec. if the AC electric power has a frequency of 50 Hz and in 16.7 msec. if the AC electric power has a frequency of 60 Hz. In addition, the DC component detecting circuit 40 is not adversely affected by frequency changes in principle. Consequently, even when the inverter device 12 intentionally changes its output frequency for the purpose of detecting an independent operation mode, the DC component detecting circuit 40 can detect a DC component stably irrespective of such a change in the output frequency of the inverter device 12. Furthermore, even if the PWM rectangular voltage waveform from the inverter device 12 contains a lot of harmonic components, since such harmonic components have symmetric waveforms in nature, they are canceled in the positive and negative periods in calculating the areas of the waveforms, and do not adversely affect the detection of the DC component.

As with the first embodiment, the DC component detecting circuit 40 does not require a complex filter. The DC component detecting circuit 40 is of a simple circuit arrangement as it directly detects an AC voltage from the output line of the inverter device. Because the DC component detecting circuit 40 produces a DC output in principle, the controller 19 can process the output signal from the DC component detecting circuit 40 simply and quickly without undue burdens on a CPU thereof.

As the DC component detecting circuit 40 directly detects an AC voltage from the output line of the inverter device, it does not suffer the problem of a temperature drift as described above. The DC component detecting circuit 40 is capable of detecting the addition of a DC component by 0.5% to the AC output power within 0.5 second, and is reduced in size and made compact.

### INDUSTRIAL APPLICABILITY

The present invention is applicable to a circuit and a system for detecting a DC component contained in an AC output of an inverter device for grid-connection, accurately within a short period of time.

1. A DC component detecting circuit for detecting a DC component contained in an output power of a grid-connection inverter device, comprising:
a current detector for outputting a current signal or a voltage signal which is proportional to an output current of the inverter device;
a separating circuit for separating the detected signal from said current detector into signals in respective positive and negative half periods;
an integrating circuit for integrating the separated signals in the respective positive and negative half periods; and
an adding circuit for adding integral signals in the respective positive and negative half periods from said integrating circuit.

2. A DC component detecting circuit according to claim 1, wherein said separating circuit comprises two diodes or two ideal diode circuits connected to an output terminal of said current detector and oriented such that currents flow in opposite directions therethrough.

3. A DC component detecting circuit according to claim 1, wherein said integrating circuit comprises a CR-type analog integrating circuit.

4. A DC component detecting circuit according to claim 1, further comprising:
memory means for holding calibrating information for said detected signal depending on a temperature drift of said current detector, such that the detected signal representative of the DC component is calibrated based on the calibrating information stored by said memory means.

5. A DC component detecting circuit according to claim 4, further comprising:
a second current detector, which is structurally identical to said current detector, selectively connected to or bypassing the same output line of said inverter device as said current detector is connected, such that the sum of the DC component contained in the output power of said inverter device and the temperature drift is detected based on the detected signal from said current detector, only a DC component is acquired by said second current detector, and the difference between the detected signal from said current detector and the DC component from said second current detector is calculated as temperature drift calibrating information to calibrate the detected signal from said current detector.

6. A DC component detecting system for detecting a DC component contained in an output power of a grid-connection inverter device, comprising:
a grid-connection inverter device;
a current detector for outputting a voltage which is proportional to an output current of the inverter device;
a DC component detecting circuit for separating a detected signal from said current detector into signals in respective positive and negative half periods, integrating the separated signals in the respective positive and negative half periods, and adding integral signals from said integrating circuit in the respective positive and negative half periods to output a DC component of said detected signal;
memory means for storing calibrating information for said detected signal depending on a temperature drift of said current detector; and
means for calibrating said DC component based on the calibrating information stored by said memory means.

7. A DC component detecting circuit for detecting a DC component contained in the output power of a grid-connection inverter device, comprising:
a voltage detector for directly detecting and outputting an output voltage of the inverter device;
a separating circuit for separating the detected signal from said current detector into signals in respective positive and negative half periods;
an integrating circuit for integrating the separated signals in the respective positive and negative half periods; and
an adding circuit for adding integral signals in the respective positive and negative half periods from said integrating circuit.
